(19) United States
(12) Patent Application Publication
(10) Pub. No.: US 2005/0136638 A1
(43) Pub. Date: Jun. 23, 2005

(54) Low temperature sintering nanoparticle compositions

(75) Inventors: Jessica L. Voss-Kehl, Inver Grove Heights, MN (US); Todd D. Jones, St. Paul, MN (US); Christopher P. Gerlach, St. Paul, MN (US); Carl R. Kessel, St. Paul, MN (US); Tommie W. Kelley, Coon Rapids, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 10/739,623

(22) Filed: Dec. 18, 2003

(51) Int. Cl. H01L 21/00; H01L 23/48

(52) U.S. Cl. 438/610; 257/746; 257/753; 438/628; 257/762; 438/687

(57) ABSTRACT

A composition contains a mixture of silver and gold metallic nanoparticles. The composition can be deposited on a substrate and sintered to form a conductive element.

### BACKGROUND

The electronics industry has increasingly moved toward the production of low cost electronics formed on polymeric substrates. Such polymeric substrates include, for example, polyethylene, polypropylene, polyimide, and polyester. These substrates are relatively inexpensive to make, are stable, and offer good adhesion of electronic components.

Unfortunately, significant limitations exist with regard to the use of polymeric substrates. One of the greatest such limitations is the requirement that polymeric substrates be processed at low-temperatures, typically below 200° C. These low processing temperatures can be a significant problem in the production of electronics, in particular for applications that require high temperature sintering of metals to produce a conductive layer on the polymeric substrate.

Therefore, a need exists for materials and methods for producing conductive layers on a polymeric substrate that do not require high temperature sintering.

### SUMMARY

The present invention is directed to a composition containing a mixture of silver and gold nanoparticles, methods of forming conductive elements using the mixture, and articles containing these conductive elements. The mixture may be inkjet printable to form a printed composition that can be sintered at relatively low sintering temperatures to produce a conductive element. The nanoparticle mixture, also referred to herein as an ink, can typically be sintered at temperatures at or below 250° C. In most implementations, it can be sintered at temperatures at or below 200° C., which is low enough to enable electronics development on many polymeric substrates. In addition, this low sintering temperature is advantageous for use on non-polymeric substrates, such as glass, because it typically allows sintering to be performed with the addition of less total energy than required for higher-temperature sintering, and/or less thermal stress.

The nanoparticle mixture contains metal nanoparticles and also contains a liquid delivery medium. The majority of the metal nanoparticles are usually silver and gold nanoparticles, although other metals may also be added in some implementations. Generally, the amount of silver is significantly greater than the amount of gold used in the composition. The ratio of silver to gold can be, for example, at least 1 to 1, 5 to 1, or even at least 10 to 1, by weight.

By definition, nanoparticles have an average particle diameter ranging from 1-100 nanometers (nm). For, example, the nanoparticles can have an average particle diameter of from at least 1 up to and including to 10, 25, or even 70 nm. In certain embodiments, the silver nanoparticles are significantly larger than the gold nanoparticles, sometimes twice the average size as the gold nanoparticles. In an example embodiment, the nanoparticles of silver have an average particle diameter of approximately 7 nm, while the gold nanoparticles have an average particle diameter of approximately 4 nm in diameter, resulting in a composition that sinters at 200° C. However, it will be appreciated that nanoparticles used in accordance with the invention can vary from these specific values.

Various features and advantages of the invention will be apparent from the following detailed description of the invention and the claims. The above summary is not intended to describe each illustrated embodiment or every implementation of the present disclosure. The detailed description that follows more particularly exemplifies certain preferred embodiments utilizing the principles disclosed herein.

### DETAILED DESCRIPTION

The present invention is directed, in part, to methods of forming one or more conductive elements on a substrate. The methods include providing a substrate, such as a polymeric substrate. Onto this substrate is deposited a substantially non-agglomerated dispersion of silver and gold nanoparticles of an average size less than 100 nm in a liquid delivery medium. Thereafter, the deposited dispersion is sintered at a temperature at or below 250° C. to form the conductive element.

The invention is further directed to an electronic article comprising a substrate and a conductive element on the substrate. The conductive element, which may have any pattern, is formed by depositing a composition comprising a dispersion of silver and gold nanoparticles in a liquid delivery medium. After deposition, the composition is sintered at a temperature at or below 200° C.

The nanoparticle mixture of the invention contains metal nanoparticles in a liquid delivery medium. The majority of the metal nanoparticles are usually silver and gold nanoparticles, although other metals may also be added in some implementations. Generally, the amount of silver is significantly greater than the amount of gold used in the composition. The ratio of silver to gold can be, for example, at least 1 to 1, 5 to 1, or even at least 10 to 1, by weight. Without being bound by theory, it is believed that the addition of gold nanoparticles decreases the sintering temperature of the composition, while the silver nanoparticles maintain the conductivity and increase film cohesion and adhesion to a substrate after sintering.

As used herein, “substantially non-agglomerated” means measured average particle diameter is within a factor of two of the average primary particle diameter. Aggregate particle diameter is typically measured using light scattering techniques known in the art. Primary particle diameter is typically measured using transmission electron microscopy.

The nanoparticles are typically of a mean diameter ranging from 1-100 nanometers (nm), and are advantageously as small as possible. The nanoparticles can be from 1 to 70 nm in diameter. In general, the nanoparticles are less than 25 nm in diameter, more desirably less than 10 nm in diameter.

In certain embodiments, the silver nanoparticles are significantly larger than the gold nanoparticles, sometimes twice the average size as the gold nanoparticles. In an example embodiment, the nanoparticles of silver are approximately 7 nm in diameter, while the gold nanoparticles are approximately 4 nm in diameter, resulting in a composition that sinters at 200° C. However, it will be appreciated that nanoparticles used in accordance with the invention can vary from these specific values. Average particle diameter refers to the number average particle diameter and is measured by transmission electron microscopy. Another method to measure particle diameter is dynamic light scattering, which measures weight average particle diameter. In the practice of the present invention, particle diameter may be determined using any suitable technique.

In general, it is desirable to limit the agglomeration of the nanoparticles. To prevent particle agglomeration and settling, the metal nanoparticles can be surface treated. Suitable surface treatments include alcohols, such as decanol, to prevent clumping and clustering of the nanoparticles, thereby aiding in their deposition on a substrate. Additional surface treatments include thiols, surfactants, and carboxylic acids. Additional surface modification techniques and materials include those disclosed in U.S. Pat. No. 6,586,483 to Kolb et al.

Any solid substrate may be used. Useful substrates may comprise, for example, at least one of organic polymer such as, for example, polyethylene, polypropylene, polyimide, polyester (e.g., polyethylene naphthalate), or a combination thereof; ceramic; metal; glass; or a combination thereof. Useful substrates include, for example, flexible substrates (e.g., a flexible polymeric film), rigid substrates (e.g., a glass or ceramic plate), and other substrates.

The composition may be deposited on a substrate using various methods, including digital and non-digital application methods. Useful non-digital application methods include, for example, screen printing, gravure coating, spraying, and microcontact stamping. Useful digital application methods include, for example, spray jet, valve jet, and inkjet printing methods. Techniques and formulation guidelines are well known (see, for example, “Kirk-Othmer Encyclopedia of Chemical Technology”, Fourth Edition (1996), volume 20, John Wiley and Sons, New York, pages 112-117, the disclosure of which is incorporated herein by reference) and are within the capability of one of ordinary skill in the art. Combinations of these methods may also be employed in practice of the present invention.

Of these methods, inkjet printing methods are typically well suited for applications in which fine resolution is desired. Inkjet printing is highly versatile in that printing patterns can be easily changed, whereas screen printing and other mask-based techniques require a different screen or mask to be used with each individual pattern. Thus, inkjet printing does not require a large inventory of screens or masks that need to be cleaned and maintained. Also, additional compositions can be inkjet printed onto previously formed layers to create larger (e.g., taller) layers and multilayered electronic elements.

Exemplary inkjet printing methods include thermal inkjet, continuous ink-jet, piezo inkjet, acoustic inkjet, and hot melt inkjet printing. Thermal inkjet printers and/or print heads are readily commercially available, for example, from Hewlett-Packard Company (Palo Alto, Calif.), and Lexmark International (Lexington, Ky.). Continuous inkjet print heads are commercially available, for example, from continuous printer manufacturers such as Domino Printing Sciences (Cambridge, United Kingdom). Piezo inkjet print heads are commercially available, for example, from Trident International (Brookfield, Conn.), Epson (Torrance, Calif.), Hitachi Data Systems Corporation (Santa Clara, Calif.), Xaar PLC (Cambridge, United Kingdom), Spectra (Lebanon, N.H.), and Idanit Technologies, Limited (Rishon Le Zion, Israel). Hot melt inkjet printers are commercially available, for example, from Xerox Corporation (Stamford, Conn.).

Thus, the composition may have a viscosity making it amenable to inkjet printing onto a substrate. Typically, the composition has a viscosity of 1 to 40 millipascal-seconds at the print head temperature, measured using continuous stress sweep over shear rates of 1 second⁻¹ to 1000 second⁻¹; and frequently a viscosity of 10 to 14 millipascal-seconds measured using continuous stress sweep, over shear rates of 1 second⁻¹ to 1000 second^{-1.}

The composition comprises a liquid delivery medium. The liquid delivery medium may comprise one or more solvents. The liquid delivery medium may be present in amount sufficient to adjust the viscosity of the composition, for example, to a viscosity suitable for a chosen application method. For example, if inkjet printing is chosen as the application method, the composition may be adjusted by addition of solvent to a viscosity of less or equal to 30 millipascal-seconds at 60° C. Exemplary solvents include water, organic solvents (e.g., mono-, di- or tri-ethylene glycols or higher ethylene glycols, propylene glycol, 1,4-butanediol or ethers of such glycols, thiodiglycol, glycerol and ethers and esters thereof, polyglycerol, mono-, di- and tri-ethanolamine, propanolamine, N,N-dimethylformamide, dimethyl sulfoxide, dimethylacetamide, N-methylpyrrolidone, 1,3-dimethylimidazolidone, methanol, ethanol, isopropanol, n-propanol, diacetone alcohol, acetone, methyl ethyl ketone, propylene carbonate), and combinations thereof.

The composition may contain one or more optional additives such as, for example, colorants (e.g., dyes and/or pigments), thixotropes, thickeners, or a combination thereof.

The compositions may be used in a wide variety of electronic devices. Examples include sensors, touch screens, transistors, diodes, capacitors (e.g., embedded capacitors), and resistors, which can be used in various arrays to form amplifiers, receivers, transmitters, inverters, and oscillators.

### EXAMPLES

These examples are merely for illustrative purposes only and are not meant to be limiting on the scope of the appended claims. All parts, percentages, ratios, etc. in the examples and the rest of the specification are by weight, unless noted otherwise. Unless otherwise noted, all reagents used in the examples were obtained, or are available, from general chemical suppliers such as, for example, Sigma-Aldrich Company, Saint Louis, Mo., or may be synthesized by conventional methods.

TABLE OF ABBREVIATIONS

| Abbreviation | Description |
|---|---|
| Silver Ink-1 | A silver nanoparticulate ink obtained from Harima Chemical |
| | Company; Tokodai, Japan, as “NPS-J” used as received as a stable |
| | dispersion of approximately 58 percent by weight 7 nanometer |
| | silver particles, surface treated with decanol and dispersed in n- |
| | tetradecane, as described in JP200266002A. |
| Silver Ink-2 | A silver nanoparticulate ink that was not substantially |
| | agglomerated. Formed using Sumitomo Nanosilver Lot |
| | #SAg030424D, a 50 nm silver nanoparticulate composition from |
| | Sumitomo Electric Company; Torrance, California, received as a |
| | dry powder and subsequently prepared as a stable dispersion of 20 |
| | percent by weight silver, surface treated with propionic acid and |
| | dispersed in isopropanol. |
| Gold Ink-1 | Prepared from gold nanoparticles made by the chemical synthesis method |
| | shown below (using the method described by M. Brust, et |
| | al. in J. Chem. Soc. Chem. Comm., 1994, page 801) which were |
| | added to n-tetradecane and sonicated in an ultrasonic water bath |
| | for 30 minutes to produce a stable dispersion of gold nanoparticles |
| | of from 43-55 percent by weight gold. |
| Gold Ink-2 | Prepared from gold nanoparticles made by the chemical synthesis |
| | method shown below (using the method described by M. Brust, et |
| | al. in J. Chem. Soc. Chem. Comm., 1994, page 801) which were |
| | added to isopropanol and propionic acid and sonicated in an |
| | ultrasonic water bath for 30 minutes to produce a dispersion of |
| | gold nanoparticles of from 20 percent by weight gold, and |
| | containing 1 percent by weight propionic acid. |
| n-tetradecane | Commercially available from Avocado Research Chemicals, Ltd; |
| | Lancashire, England. |
| HTCA | Hydrogen tetrachloroaurate, commercially available from Alfa |
| | Aesar |
| TOAB | tetraoctylammonium bromide |

Preparation of Gold Nanoparticles

Gold nanoparticles were prepared following this general description. A solution of 1.33 grams of HTCA 100 milliliters of purified water was added to a solution of 6.00 grams of TOAB in 200 milliliters of toluene in a round-bottom flask. This two-phase system was stirred for 20 minutes, during which time the gold transferred from the aqueous to the organic phase, as observed by the change in color of the two phases. 1.0 milliliter of 1-hexanethiol was added to the organic phase, and the resulting mixture was stirred for an additional 10 minutes. The deep orange color of the organic phase faded significantly during this time period. To the flask was added 75 milliliters of a 15 grams/liter solution of sodium borohydride in purified water, over a period of ˜10 minutes. The organic phase immediately changed to a deep reddish brown color. The mixture was stirred overnight at room temperature. The organic phase was separated from the aqueous phase, reduced on a rotary evaporator to a total volume of ˜50 milliliters, and precipitated into approximately 800 milliliters of ethanol. After standing for several hours at ˜0° C., the nanoparticles were collected by vacuum filtration and dried, yielding ˜0.5 g of thiol-stabilized nanoparticles.

Resistivity Test

The resistivity of coatings was measured using a MODEL 717 CONDUCTANCE MONITOR commercially available from Delcom Instruments, Inc., Prescott, Wis., which was operated at a frequency of 1 MHz, or using a model SRM-232-2000 Surface Resistivity Meter commercially available from Guardian Manufacturing, Rockledge, Fla. The results are reported in ohms per square (ohm/square).

### Examples 1-3 and Comparative Example C1

For Comparative Example C1 the Silver Ink-1 was used as obtained without further modification. For Examples 1-3 the Silver Ink-1 was added to the Gold Ink-1 such that the total metal nanoparticle content was 57.6 percent by weight in each formulation as reported in Table 1. Each of Examples 1-3 was sonicated in an ultrasonic water bath for 30 minutes after mixing to produce an ink dispersion.

TABLE 1

| | | | Amount of n- | |
|---|---|---|---|---|
| | | Silver Ink-1 | tetradecane | Gold Ink-1 |
| | | Added, | present, | Added, |
| Example | Ag:Au Ratio | grams | grams | grams |
| Example 1 | 1.4:1 | 1.12 | 0.40 | 0.48 |
| Example 2 | 1:1 | 0.96 | 0.46 | 0.58 |
| Example 3 | 8.6:1 | 1.72 | 0.16 | 0.12 |

Preparation of Coatings

Examples 1-3 and Comparative Example C1 were each coated onto three glass microscope slides (12 slides total), using a #6 Mayer rod. The coated slides were placed in a 100° C. oven for 10 minutes, to remove some of the solvent and generate a more even coating. The coated slides were sintered for 15 minutes at 150° C., 200° C., and 250° C., respectively. Sintering was detected as an increase in grain size by obtaining Scanning Electron Micrographs using a Hitachi S-4700 cold field emission SEM. A summary of these observations are reported in Table 2 (below):

TABLE 2

| | Sintering | Sintering | |
|---|---|---|---|
| | Detected in | Detected in | Sintering Detected |
| Ink | 150° C. Coating? | 200° C. Coating? | in 250° C. Coating? |
| Comparative | No | No | Yes |
| Example C1 | | | |
| Example 1 | No | Yes | Yes |
| Example 2 | No | Yes | Yes |
| Example 3 | No | Yes | Yes |

Resistivity

Resistivity was measured as described above for each of the sintered coatings. The results are reported in Table 3 (below).

TABLE 3

| | Resistivity | Resistivity | |
|---|---|---|---|
| | of 150° C. | of 200° C. | Resistivity |
| | Coating, | Coating, | of 250° C. Coating, |
| Example | ohms/square | ohms/square | ohms/square |
| Comparative | Non-conductive | Non-conductive | 0.163 |
| Example C1 | | | |
| Example 1 | Non-conductive | 0.617 | 0.403 |
| Example 2 | Non-conductive | 0.546 | 0.667 |
| Example 3 | Non-conductive | 0.189 | 0.154 |

### Example 4 and Comparative Example C2

Example 4 was a blend of Silver Ink-2 and Gold Ink-2 with a ratio of Ag:Au of 8.6:1, formulated generally as described for Example 1 above. Comparative Example C2 was Silver Ink-2.

The inks of Example 4 and Comparative Example C2 were each coated onto three glass microscope slides (6 slides total), using a #6 Mayer rod. The coated slides were placed in a 100° C. oven for 10 minutes, to remove some of the solvent and generate a more even coating. The coated slides were sintered for 15 minutes at 150° C., 200° C., and 250° C., respectively. Resistivity was measured as described above using the Guardian Surface Resistivity Meter. Results are reported in Table 4 (below).

TABLE 4

| | Resistivity of | Resistivity of | Resistivity |
|---|---|---|---|
| | 150° C. Coating, | 200° C. Coating, | Coating, of 250° C. |
| Ink | ohms/square | ohms/square | ohms/square |
| Comparative | >2,000 | >2,000 | >2,000 |
| Example C2 | | | |
| Example 4 | >2,000 | 70 | 30 |

The complete disclosures of the patents, patent documents and publications cited herein are incorporated by reference in their entirety as if each were individually incorporated.

Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows.

1. A method of forming a conductive element on a substrate, the method comprising:
providing a substrate;
depositing onto the substrate a substantially non-agglomerated dispersion of silver and gold nanoparticles of an average particle diameter in a range of from at least 1 nanometer up to and including 100 nanometers in a liquid delivery medium; and
sintering the deposited dispersion at a temperature at or below 250° C. to form the conductive element.

2. The method of forming a conductive element of claim 1, wherein the deposited dispersion is sintered at a temperature at or below 200° C.

3. The method of forming a conductive element of claim 1, wherein the substrate is polymeric.

4. The method of claim 3, wherein the substrate is selected from the group polyethylene, polypropylene, polyimide, and polyester.

5. The method of claim 1, wherein the ratio of silver to gold metallic nanoparticles is at least 10 to 1.

6. The method of claim 1, wherein the ratio of silver to gold metallic nanoparticles is at least 5 to 1.

7. The method of claim 1, wherein the liquid delivery medium comprises organic solvent.

8. The method of claim 1, wherein the gold nanoparticles have an average particle diameter of less or equal to 10 nanometers.

9. The method of claim 1, wherein the silver nanoparticles have an average particle diameter of less than or equal to 10 nanometers.

10. The method of claim 1, wherein the nanoparticles are surface modified.

11. The method of claim 1, wherein depositing comprises digitally applying.

12. The method of claim 1, wherein depositing comprises inkjet printing.

13. A composition comprising a dispersion of silver and gold nanoparticles in a liquid delivery medium, the composition comprising a mixture of metallic nanoparticles, wherein the mixture comprises silver and gold nanoparticles in a ratio of at least 1 to 1 by weight.

14. The composition of claim 13, wherein the silver nanoparticles have an average particle diameter of less than 70 nanometers.

15. The composition of claim 13, wherein the silver nanoparticles have an average particle diameter of less than 10 nanometers.

16. The composition of claim 13, wherein the gold nanoparticles have an average particle diameter of less than 70 nanometers.

17. The composition of claim 13, wherein the gold nanoparticles have an average particle diameter of less than 10 nanometers.

18. The composition of claim 13, wherein the composition is sinterable at a temperature at or below 200° C.

19. An electronic device comprising:
a substrate; and
a conductive element on the substrate, the conductive element formed by depositing a dispersion of silver and gold nanoparticles in a liquid delivery medium, the composition comprising a mixture of metallic nanoparticles, wherein the mixture comprises silver and gold nanoparticles in a ratio of at least 1 to 1 by weight, and sintering the deposited dispersion at a temperature at or below 200° C.

20. The electronic device of claim 19, wherein the substrate is multilayered.

21. The electronic device of claim 19, wherein the conductive element is a layer of a multilayer device.

22. The electronic device of claim 19, wherein the electronic device comprises a touch screen.

23. The electronic device of claim 19, wherein the substrate comprises a flexible substrate.
